(19) United States
(12) Patent Application Publication
(10) Pub. No.: US 2012/0080787 A1
(43) Pub. Date: Apr. 5, 2012

(54) Electronic Package and Method of Making an Electronic Package

(75) Inventors: Milind P. Shah, San Diego, CA (US); Omar J. Bchir, San Diego, CA (US); Sashidhar Movva, San Diego, CA (US)

(73) Assignee: QUALCOMM INCORPORATED, San Diego, CA (US)

(21) Appl. No.: 13/220,733

(22) Filed: Aug. 30, 2011

Related U.S. Application Data
(60) Provisional application No. 61/389,731, filed on Oct. 5, 2010.

(51) Int. Cl. H01L 23/498; H01L 21/56; H01L 23/48

(52) U.S. Cl. 257/737; 257/777; 438/127; 257/E23.068; 257/E23.01; 257/E21.502

(57) ABSTRACT

An electrical package and a method of forming the electrical package, where the electrical package has a substrate with a frontside, an intergrated circuit coupled to the frontside of the substrate, and at least one non-collapsible metal connector created on the frontside of the first substrate.

### RELATED APPLICATION

This application claims priority and the benefit of U.S. Provisional application, Ser. No. 61/389,731 filed Oct. 5, 2010.

### FIELD OF DISCLOSURE

This disclosure relates generally to integrated circuit packaging, and in particular to package on package systems.

### BACKGROUND

Package on Package (“POP”) is a packaging system that allows one IC package to be coupled to another IC package providing more functionality in less space. Signals may be routed through each package.

Coupling of IC packages is desirable and may reduce the size of the end user device. FIG. 1A shows an exemplary POP system 100. A first die 104 is mounted onto a first package substrate 108. The package substrate 108 has solder balls 112 on a front side 116 of the package substrate 108. The solder balls 112 provide electrical connectivity to a second substrate package 120 through conducting pads 128. A mold compound 124 is formed over the solder balls 112. A second package 126 is formed over the solder balls and die 104 to form a package on package system.

Disadvantages exist in shrinking the thickness of the bottom package 122. For example, if the height of the solder ball 112 is reduced, the pitch between the solder balls decreases. The pitch is the distance between each solder ball 112. As the pitch decreases, bridging problems with the solder balls occur during reflow of the solder balls 112. Reflow process is applied so that the solder balls 112 provide an attachment mechanism between package to package stacks.

FIG. 1B shows an exemplary POP system 100 after a reflow process is applied. After reflow, bridging may result in electrical shorts 114 and reduce signaling capability between the packages and between the IC die and other surrounding circuits, reducing reliability of the POP system. Another disadvantage of the POP system 100 is that the solder ball attach is generally performed after the IC die 104 is attached to the substrate 108. Because the package system 100 cannot be tested for functionality until after the IC die 104 is attached, the IC die may need to be discarded if the package is found to be not functioning properly. This results in increased expenses.

Therefore, it would be desirable to develop an improved electronic package-on-package system without these disadvantages.

### BRIEF DESCRIPTION OF THE DRAWINGS

FIG. 1A is a graphical illustration of a cross-sectional view of a package-on-package system;

FIG. 1B is a graphical illustration of a package-on-package system illustrating solder ball bridging;

FIG. 2 is a flow chart illustrating an exemplary packaging process employing non-collapsible metal connectors that provide electrical connections between packages;

FIG. 3A-3J is a graphical illustration of a cross-sectional view of an exemplary packaging process employing copper cylinder connectors that provide electrical connections between packages;

FIG. 4 is a block diagram showing an exemplary wireless communication system in which it may be advantageous to use a package-on-package system.

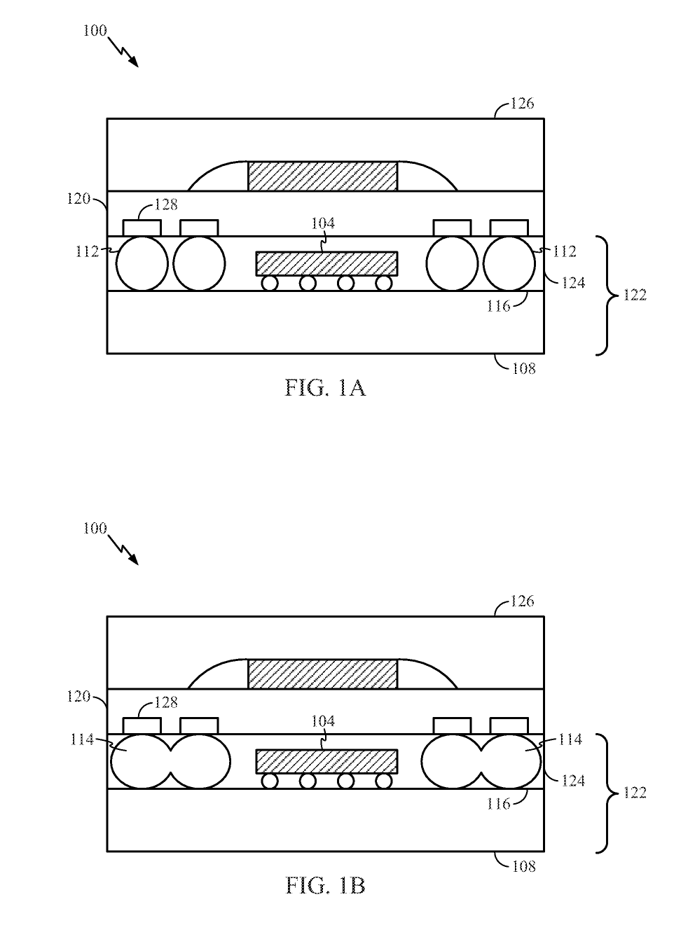

### DETAILED DESCRIPTION

Inventive aspects are disclosed in the following description and related drawings directed to specific embodiments. Alternate embodiments may be devised without departing from the scope of the invention. Additionally, well-known elements may not be described in detail or may be omitted so as not to obscure relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments include the discussed feature, advantage or mode of operation. The terminology used herein is for the purpose of describing particular embodiments. The described embodiments are to illustrate the teachings of the invention and are not intended to limit the embodiments of the invention described.

Package on package (“POP”) systems may be accomplished through the use of non-collapsible metal connectors in place of solder balls for electrical connection between POP systems. Examples of non-collapsible metals include tin, gold, nickel, chrome and copper. The non-collapsible metals may be formed into three dimensional connector shapes including cylindrical, rectangular, or eliptical shapes. For example, a copper cylinder may be used in place of solder balls for electrical connection between POP systems. However, embodiments of the invention are not so limited to these formations.

Use of non-collapsible metal connectors allows the height of the bottom package to be reduced without reduction of electrical connection reliability. This is because non-collapsible metal may not require the common solder ball reflow process which may spread or widen when reflow occurs. Therefore because non-collapsible metal does not require reflow and does not spread, there is no bridging. Thus electrical reliability is increased. Additionally, non-collapsible metal connectors may allow greater flexibility and reduced costs because whereas solder ball fabrication is generally performed by an assembly house, non-collapsible metal connectors may be formed by the substrate manufacturer. This allows the package to be tested prior to attaching the die and avoids having to discard the die where the package is found not to be functioning properly.

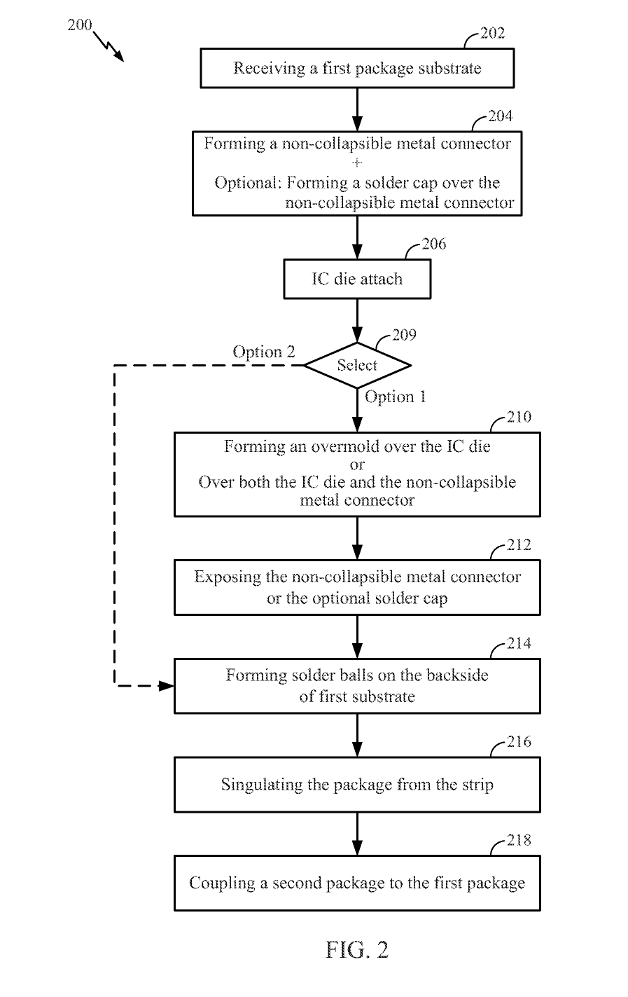

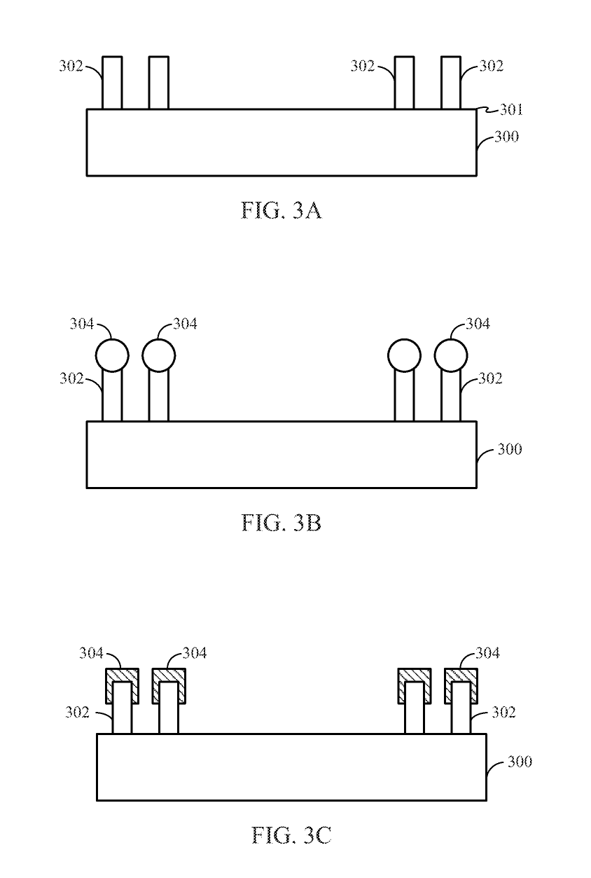

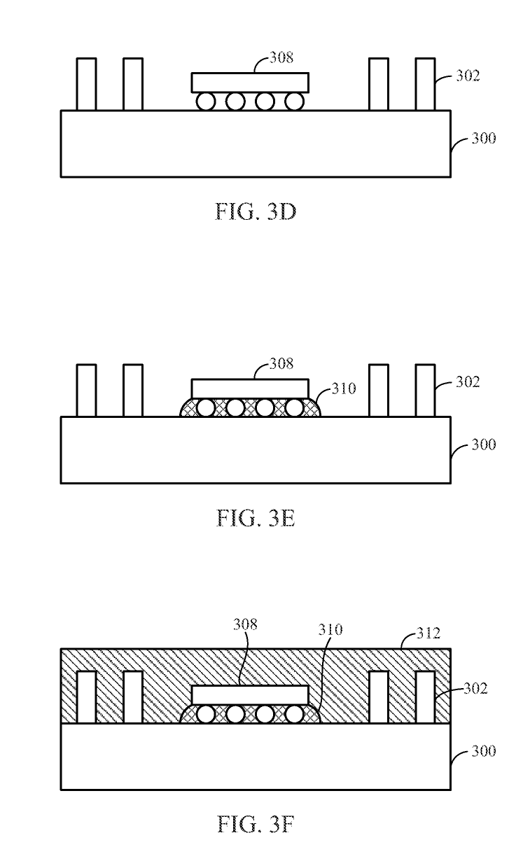

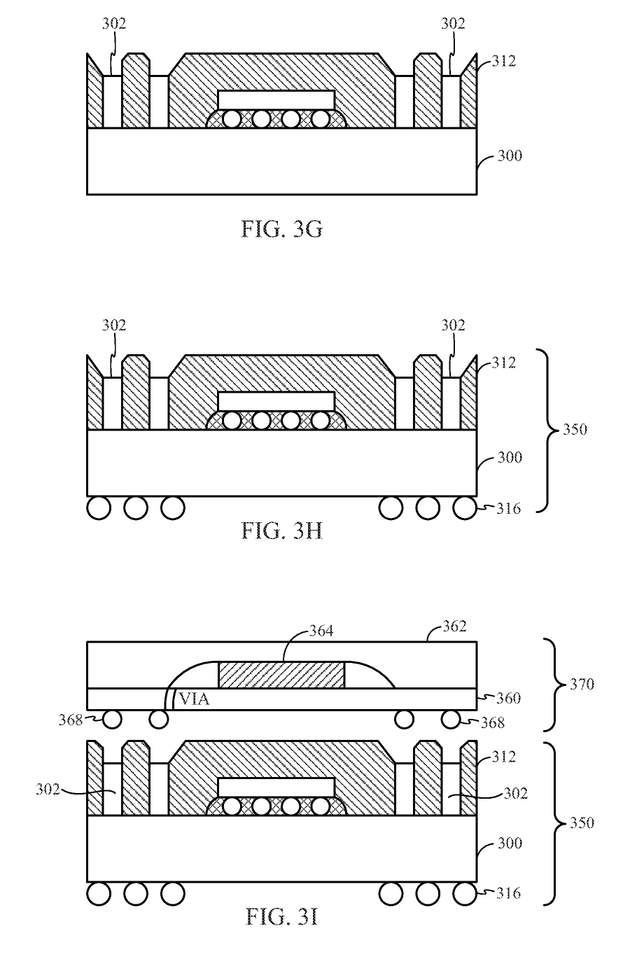

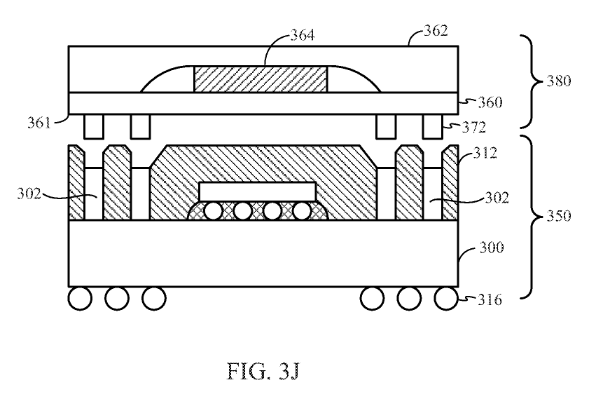

FIG. 2 is a flow chart illustrating an exemplary POP process. A POP process begins at block 202 by receiving a package substrate. FIG. 3A is an illustration of a cross sectional view of an exemplary first package substrate 300. The substrate may be formed from any suitable material, including organic material or inorganic material or a combination of both. For example, the substrate may be formed of glass or silicon or ceramic. At block 204 of FIG. 2, one or more non-collapsible metal connectors are formed, for example, by a lithographic mask and electrolytic plating. FIG. 3A illustrates as an example, copper cylinder connectors 302 formed on the substrate 300 The copper cylinder connectors are formed on the frontside 301 of the substrate 300. FIGS. 3B and 3C illustrate an optional solder cap 304 which may be formed over the copper cylinders 302.

Because the copper cylinder connectors 302 do not themselves reflow, the width, diameter and pitch of the copper cylinder connectors 302 are more easily maintained. Pitch is the distance between each copper cylinder. The height of the copper cylinder connector may be designed independent of pitch considerations. That is, the height of the copper cylinder may be reduced without consideration of the bridging problems suffered by the solder ball connect method. Therefore the height of the copper cylinder may be reduced, even if a tight pitch is desired.

In one embodiment, the copper cylinder connector is designed to have reduced height in order to minimize the size of the package height. For example, the height of the copper cylinder may be at about the same height of an IC die which may be later attached to the substrate. In an alternative embodiment, where the IC die is embedded within the first substrate 300, the height of the copper cylinder may be reduced to the height necessary to make the connection between a first package and a second package. The pitch may be designed independently to the desired number of inputs/outputs between each stacked package. In an exemplary embodiment, the pitch may vary between the copper cylinders 302 as may the actual diameters of the copper cylinders. In another exemplary embodiment, the pitch may be constant between copper cylinders 302. As the pitch shrinks, the diameter of the copper cylinders may shrink to further accommodate a smaller package and maintain a minimum number of input/outputs.

The exemplary process continues at block 206 an IC die is attached to the substrate 300. The term IC die is defined to include any type of IC device, chip or logic device. Any method of die attach may be used, including for example a flip chip, direct die attach, or wire bonding. FIG. 3D is a cross sectional view of an exemplary IC die shown as a flip chip 308 attached to the substrate 300. To provide additional stability to the flip chip 308 attached to the substrate 300, underfill molding 310 may be applied as shown in FIG. 3E. However, the underfill molding 310 may be omitted if not desirable. For example, if wire bonding is used as the IC die attach method at block 206, the underfill molding 310 may be omitted.

After the IC die attach is performed 206, at block 209 either option 1 or option 2 may be selected. If option 1 is selected, at block 210 an overmold 312 may be formed over the copper cylinders 302 and over the optional solder cap 304 to encapsulate the assembly. FIG. 3F is a cross sectional view of the overmold 312 formed over the copper cylinders 302 and IC die 308. If at block 204 the optional solder cap 304 had been formed over the copper cylinder 302, then overmold 312 would also encapsulate the solder cap 304. An alternative embodiment known as flange POP may be used instead. In the flange POP alternative embodiment, the overmold is formed over the IC die 308 only and not the copper cylinders 302 or the optional solder cap 304.

As an alternative embodiment after the IC die attach is performed 206, the overmold 210 process may be omitted and a bare die methodology used instead. Bare die methodology means that no overmold is formed over the IC die 208. This alternative embodiment is illustrated at block 209 by selecting option 2 which bypasses blocks 210 and 212 and leads directly to block 214 which is described later.

At block 212, a through mold via process is performed, exposing the copper cylinder 302 either through grinding or laser. This process allows an electrical input/output connection to be made through the molding on the bottom package 350 in FIG. 3H to a second package which will be formed later in the process at block 218. FIG. 3G is a cross sectional view of the exposed copper cylinders 302 as a result of the through mold via process. If at block 204 the optional solder cap was formed over the copper cylinder, then block 212 will involve the step of exposing the top of the optional solder cap 304.

After block 206 option 1 or option 2, at block 214, solder balls are attached at the bottom of the substrate 300. FIG. 3H is a cross sectional view of the packaging system after block 214 is performed with solder balls 316. Generally the overall process 200 thus described is performed on either a package strip or singulated package. A package strip consists of many units of packages such as the one described. Therefore at block 216, singulation of the strip may occur. Singulation is the process of cutting the strip into single packages, resulting in the individual separation of a single package 350 shown in FIG. 3H. Singulation may occur prior to package on package formation at block 218.

At block 218, a second package is coupled to the first package 350 as illustrated in FIGS. 3I and 3J. FIGS. 3I and 3J shows two exemplary second packages. Note that FIGS. 3I and 3J shows the first package 350 and the second package 370 or 380 respectively, as being slightly apart in order to clearly illustrate the exemplary embodiments. However it should be understood that the first package 350 and the second package 370 or 380 are physically connected. FIG. 3I shows an exemplary second package 370 having solder balls 368 which may connect to the copper cylinders 302 on the first package, thereby electrically connecting the first package 350 and the second package 370. Alternatively, the solder balls 368 on the second package 370 may connect to the optional solder balls 304 on the first package 350.

FIG. 3J shows an exemplary second package 380 having copper cylinders 372 placed on the backside 361 of the package substrate 360 which may connect to the copper cylinders 302 on the first package 350, thereby electrically connecting the first package 350 and the second package 380.

The exemplary embodiments as disclosed herein are used to illustrate the inventive teachings. Other embodiments may be practiced without departing from the spirit and scope of the invention. For example, package 350 may be comprised of any type of IC die. Instead of a flip chip 308, there may be vertically stacked IC die or IC die located horizontally adjacent or elsewhere within the same plane. Similarly, the second package 370 may be comprised of any set of IC die. Additionally the embodiments disclosed herein are not limited to two stacked packages, but may include additional stacked packages or other packages within the same plane. The signaling through the copper cylinders 302 is not limited by the exemplary embodiments disclosed herein. For example, signaling may occur between two stacked packages 350 and 370 through the copper cylinders 302. Alternatively, signaling communication may occur between a bottom package 350 having copper cylinders 302 which is in communication with a PCB, mother board or with an IC die directly.

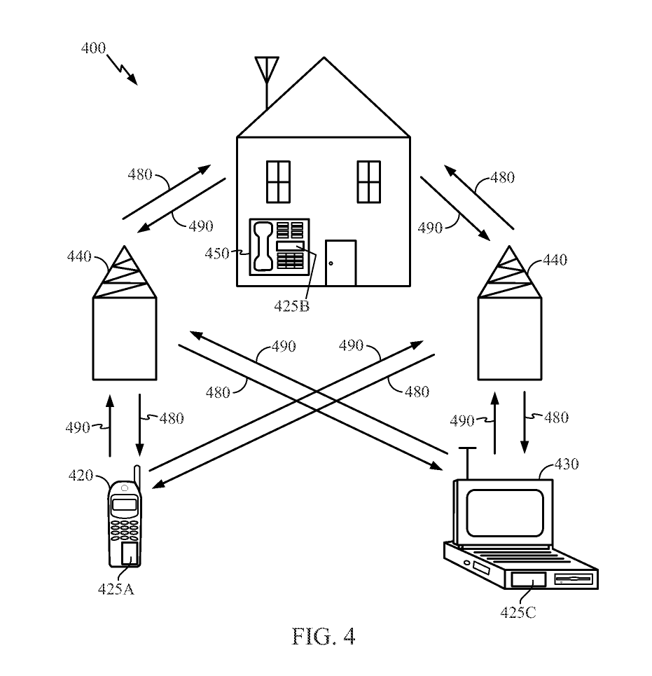

FIG. 4 shows an exemplary wireless communication system 400 in which an embodiment of an electronic package-on-package system may be advantageously employed. For purposes of illustration, FIG. 4 shows three remote units 420, 430, and 450 and two base stations 440. It should be recognized that typical wireless communication systems may have many more remote units and base stations. Any of remote units 420, 430, and 450, as well as the base stations 440, may include an electronic package-on-package system such as disclosed herein. FIG. 4 shows forward link signals 480 from the base stations 440 and the remote units 620, 630, and 650 and reverse link signals 490 from the remote units 420, 430, and 450 to base stations 440.

In FIG. 4, remote unit 420 is shown as a mobile telephone, remote unit 430 is shown as a portable computer, and remote unit 450 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 4 illustrates certain exemplary remote units that may include an electronic package-on-package system as disclosed herein, the package is not limited to these exemplary illustrated units. Embodiments may be suitably employed in any electronic device in which an electronic package-on-package system is desired.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. An electrical package comprising:
a first substrate comprising a frontside;
an IC die coupled to the frontside of the first substrate;
at least one non-collapsible metal connector created on a frontside of the first substrate.

2. The electrical package of claim 1, wherein a solder cap is disposed over the non-collapsible metal connector.

3. The electrical package of claim 1, wherein the at least one non-collapsible metal connector is formed by lithographic mask and electrolytic plating.

4. The electrical package of claim 1, further comprising at least three non-collapsible metal connectors coupling the first substrate to the second substrate.

5. The electrical package of claim 4, wherein the non-collapsible metal connectors have a plurality of pitches.

6. The electrical package of claim 4, wherein the non-collapsible metal connectors formed have a plurality of diameters.

7. The electrical package of claim 4, wherein the height of the copper pillar may be formed independent of the pitch of the copper pillars.

8. The electrical package of claim 1, wherein the IC die coupled to the first substrate is embedded within the first substrate.

9. The electrical package of claim 1, wherein the number of non-collapsible metal connectors formed are equal to a desired number of input/outputs signals.

10. The electrical package of claim 1, wherein the electrical package is coupled to a second electrical package through at least one non-collapsible metal connector.

11. The electrical package of claim 10, wherein the at least one non-collapsible metal connector acts as an input/output signaling connections.

12. The electrical package claim 1 incorporated into a device selected from a group consisting of a music player, a video player, an entertainment unit, a navigation device, a communications device, a personal digital assistant (PDA), a fixed location data unit, and a computer.

13. An electronic package-on-package system, comprising:
a first package comprising a substrate having a frontside, and an IC die coupled to the frontside of the substrate;
a second package comprising an IC die; and
a first means for coupling the first package to the second package.

14. The system of claim 13, wherein the second package is positioned substantially vertically to the second package.

15. The system of claim 13, wherein the first package further comprises a means to couple the IC die to the first package.

16. The system of claim 13, wherein the second package further comprises a means to couple the IC die to the second package.

17. A method of electronic packaging comprising:
receiving a first substrate having a frontside;
forming at least one non-collapsible metal connector on a frontside of the first substrate;
coupling an IC die to the first substrate.

18. The method of claim 17, further comprising forming a solder cap over the non-collapsible metal connector.

19. The method of claim 18, further comprising forming the solder cap by a method selected from the methods of: electrolytic plating, electroless plating, immersion, or screen printing.

20. The method of claim 19, further comprising forming an overmold over the solder cap, non-collapsible metal connector and IC die.

21. The method of claim 17, further comprising coupling a plurality of IC die to the second substrate.

22. The method of claim 17, further comprising:
forming an overmold over the non-collapsible metal connector and IC die; and
exposing the non-collapsible metal connector

23. The method of claim 17, further comprising forming solder balls on the backside of the first substrate before coupling the first substrate to the second substrate.
